(19) United States
(12) Patent Application Publication
(10) Pub. No.: US 2013/0015510 A1
(43) Pub. Date: Jan. 17, 2013

(54) Transistor, Semiconductor Device, and Method for Manufacturing the Same

(71) Applicants: Jiang Yan, Newburgh, NY (US); Lichuan Zhao, Beijing (CN)

(72) Inventors: Jiang Yan, Newburgh, NY (US); Lichuan Zhao, Beijing (CN)

(21) Appl. No.: 13/509,998

(22) PCT Filed: Aug. 9, 2011
(86) PCT No.: PCT/CN2011/001315

§ 371 Date: May 15, 2012

(30) Foreign Application Priority Data
Jul. 11, 2011 (CN) 201110192592.8

(51) Int. Cl. H01L 29/78; H01L 21/336

(52) U.S. Cl. 257/288; 438/197; 257/E29.255; 257/E21.409

(57) ABSTRACT

The invention provides a transistor, a semiconductor device and a method for manufacturing the same. The method for manufacturing a transistor comprises: defining an active area on a semiconductor substrate, forming a dummy gate stack on the active area, primary spacers surrounding said dummy gate stack, and an insulating layer surrounding said primary spacers, and forming source/drain regions embedded in said active area; removing the dummy gate in said dummy gate stack to form a first recessed portion surrounded by the primary spacers; filling Cu simultaneously in said first recessed portion and in the source/drain contact holes penetrating said insulating layer to form a gate and source/drain contacts. By filling the gate and the source/drain contact holes with the metal Cu simultaneously in the Gate Last structure, the gate serial resistance and the source/drain contact holes resistance in the Gate Last process are decreased. Besides, the effect of metal filling is improved in small scale, and the process complexity and difficulty is efficiently decreased.

### FIELD OF THE INVENTION

The present invention generally relates to semiconductor technology, and more particularly to a method for manufacturing a transistor and a semiconductor device.

### BACKGROUND OF THE INVENTION

As the CMOS device decreases continuously in size, especially in the generation of 32 nm or less, the thickness of the gate dielectric also decreases accordingly, so that the gate current leakage increases rapidly. The gate depletion layer may occur in the poly-Si gate structure used in the conventional CMOS device, so that the effective thickness of the gate oxide layer increases, which reduces the conduction current of the transistor. Besides, as the CMOS device decreases continuously in size, the size of the source/drain contact holes also decreases continuously, and the aspect ratio of the source/drain contact holes increases continuously. As a result, it is more and more difficult to fill the conventional source/drain contact holes with a metal W layer. In addition, the resistance of the source/drain contact holes also increases with decrease in size.

In the prior art, the skilled person in the art tried to alleviate one of the existing problems by the Gate Last process. For example, a high k/metal gate structure is realized by the Gate Last process. Namely, first a poly-silicon dummy gate is formed. After forming the source/drain regions and their metal silicide contacts, the poly-silicon dummy gate in the gate structure is removed. Furthermore, a metal gate material is deposited. The metal gate is generally composed of a work function metal layer and the filled metal layer. However, the problem lies in that as the gate deceases in size, it is more and more difficult to perform the filling process on the premise of a low resistance of the gate filling metal.

To this end, there is an urgent need in the art for improvements in the transistor technology.

### OBJECT AND SUMMARY OF THE INVENTION

In view of this, the present invention provides a transistor, a semiconductor device and methods for manufacturing the same, which can solve or at least alleviate at least some of the defects in the prior art.

According to the first aspect of the present invention, it is provided a method for manufacturing a transistor, which may comprise:

defining an active area on a semiconductor substrate, forming a dummy gate stack on the active area, primary spacers surrounding said dummy gate stack, and an insulating layer surrounding said primary spacers, and forming source/drain regions embedded in said active area;

removing the dummy gate in said dummy gate stack to form a first recessed portion surrounded by the primary spacers;

filling Cu simultaneously in said first recessed portion and in the source/drain contact holes penetrating said insulating layer to form a gate and source/drain contacts.

In an embodiment of the present invention, after the step of defining the active area on the semiconductor substrate, forming the dummy gate stack on the active area and the primary spacers surrounding said dummy gate stack, and before the step of forming the insulating layer surrounding said primary spacers, further comprises:

forming metal silicide in said source/drain regions.

In another embodiment of the present invention, the step of filling Cu simultaneously in said first recessed portion and in the source/drain contact holes penetrating said insulating layer to form a gate and source/drain contacts comprises:

depositing a gate work function metal layer on the surface of said first recessed portion to form a second recessed portion.

In another embodiment of the present invention, the method may further comprise:

forming two third recessed portions penetrating said insulating layer at positions corresponding to said source/drain regions.

In yet another embodiment of the present invention, the method may further comprise:

depositing a metal barrier layer on the surface of said second recessed portion and said two third recessed portions to form a fourth recessed portion and two fifth recessed portions, respectively.

In another embodiment of the present invention, the method may further comprise:

depositing Cu on the surface of said fourth recessed portion and two fifth recessed portions, so that Cu fills said fourth recessed portion and two fifth recessed portions simultaneously.

In another embodiment of the present invention, the method may further comprise:

planarizing the filled Cu to expose the insulating layer, thus forming a Cu gate and Cu source/drain contacts.

In yet another embodiment of the present invention, said step of forming a dummy gate stack over the active area may comprise:

forming a gate dielectric layer on the active area;

forming a dummy gate on said gate dielectric layer.

Preferably, said semiconductor substrate is Si substrate, said metal silicide is Ni silicide or NiPt silicide.

Preferably, said step of removing said dummy gate comprises completely removing said dummy gate.

According to the second aspect of the present invention, it is provided a method for 10 manufacturing a semiconductor device, which comprises the steps of the method for manufacturing a transistor as described above.

According to the third aspect of the present invention, it is provided a transistor, which may comprise:

an active area over a semiconductor substrate; a gate stack over the active area, primary spacers surrounding said gate stack, and an insulating layer surrounding said primary spacers; and source/drain regions embedded in said active area, and

both the gate in said gate stack and the source/drain contacts penetrating said insulating layer comprise Cu.

In an embodiment of the present invention, the method may further comprise metal silicide in the surface of the source/drain regions.

In another embodiment of the present invention, said gate stack may further comprise a gate dielectric layer over the active area and a gate over said gate dielectric layer.

In another embodiment of the present invention, said gate stack may further comprise a gate work function metal layer over said gate dielectric layer.

In yet another embodiment of the present invention, said gate stack may further comprise a metal barrier layer over said gate work function metal layer.

In another embodiment of the present invention, said gate stack may further comprise a Cu gate over said metal barrier layer.

In another embodiment of the present invention, the transistor of the present invention may further comprise a metal barrier layer between said source/drain contacts and said metal silicide.

In yet another embodiment of the present invention, said source/drain contacts may comprise Cu filled on the surface of said metal barrier layer.

Preferably, said semiconductor substrate is Si substrate, said metal silicide is Ni silicide or NiPt silicide.

According to the fourth aspect of the present invention, it is provided a semiconductor device, which comprises the transistor as described above.

By virtue of the novel design regarding a transistor in the present invention, the metal Cu, which has a low resistivity and excellent plating process for better filling, is used to replace metal W and other metals for filling the gate, and simultaneously acts as a metal material for filling the gate and source/drain contact holes. In this way, it realized to fill the gate and source/drain contact holes simultaneously with metal Cu in the “Gate Last” (also referred to as “dummy gate” in the remaining document) structure, thus decreasing the gate serial resistance and the source/drain contact holes resistance in the Gate Last process. Besides, the effect of metal filling is improved in small scale, and the process complexity and difficulty is efficiently decreased.

### BRIEF DESCRIPTION OF THE DRAWINGS

The above and other features of the present invention will be more apparent from the embodiments shown in the accompanying drawings, in which:

FIG. 1 schematically illustrates a flow chart of a method for manufacturing a transistor according to an embodiment of the present invention; and

FIGS. 2-8 schematically illustrate structural sectional views of respective intermediate structures during manufacturing a transistor according to an embodiment of the present invention.

### DETAILED DESCRIPTION OF EMBODIMENTS

Firstly, it should be noted that terms regarding position and orientation in the present invention, such as “above”, “below”, etc, refers to the direction as viewed from the front of the paper in which the drawings are located. Therefore, the terms “above”, “below”, etc regarding position and orientation in the present invention only indicate the relative positional relationship in the case as shown in the drawings. They are presented only for purpose of illustration, but not intend to restrict the scope of the present invention.

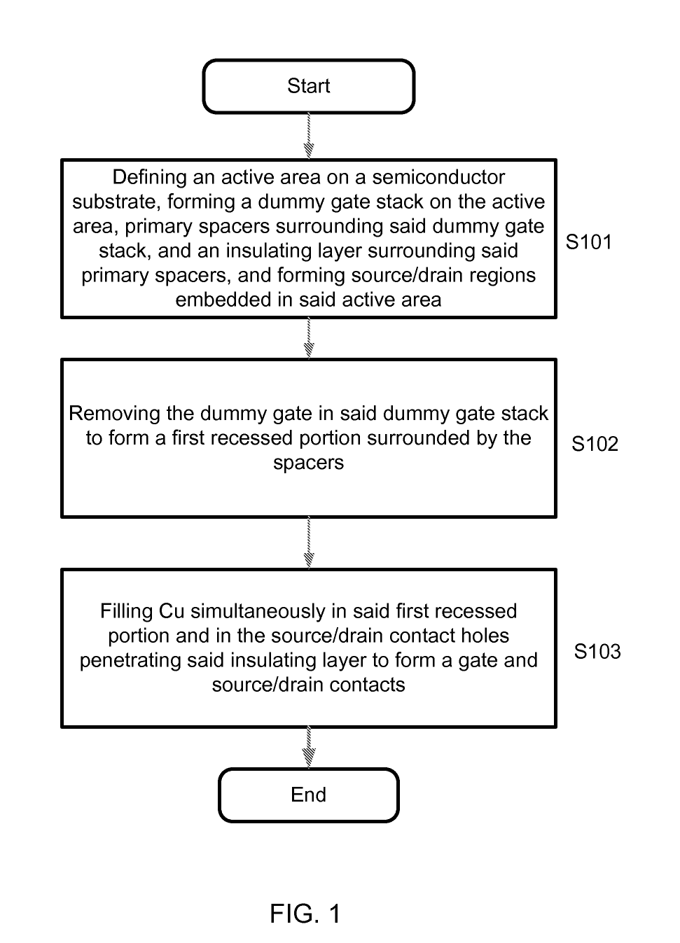

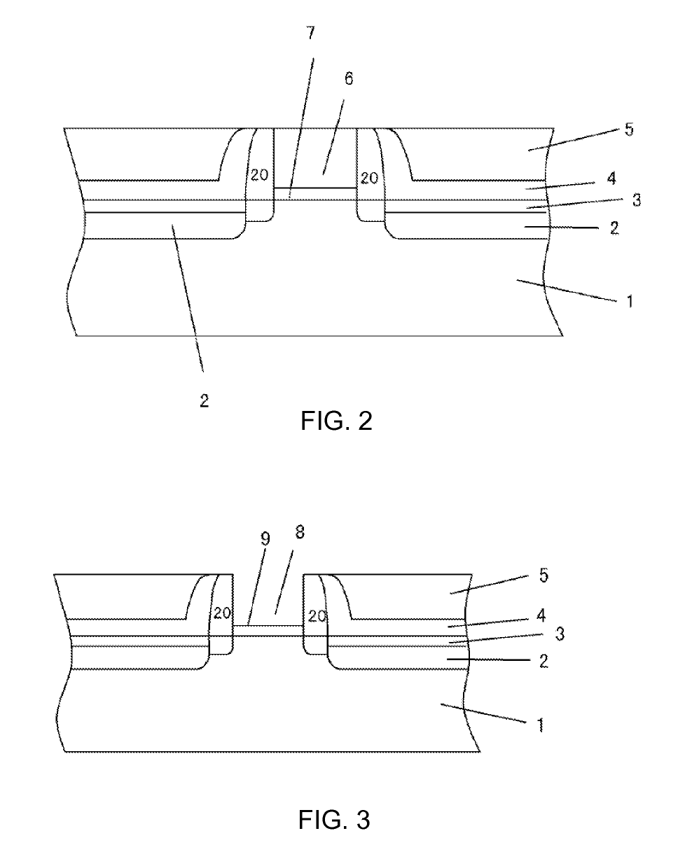

Hereinafter, the method for manufacturing the transistor of the present invention and the resulting respective transistor structures will be described in detail with reference to FIGS. 1-8 of the present invention. FIGS. 2-8 are shown by taking the Si substrate as an example. However, in addition to the Si substrate, any suitable semiconductor substrate, such as Ge substrate, SOI (silicon on insulator) substrate, and the like can be used. Therefore, the present invention is not limited to the Si substrate as shown herein.

As shown in FIGS. 1-2, in step S101, on a semiconductor substrate 1 an active area is defined, on the active area a dummy gate stack, primary spacers 20 surrounding the dummy gate stack, and an insulating layer surrounding the primary spacers 20 are formed, and source/drain regions 2 embedded in the active area are formed.

After the active area is defined on the semiconductor substrate 1, first of all, the dummy gate stack is formed. The dummy gate stack shown in FIG. 2 may comprise a gate dielectric layer 7 formed on the active area and a dummy gate 6 formed on the gate dielectric layer 7. In this embodiment, the gate dielectric layer may be SiO₂, SiN, or the combination thereof. In another embodiment, the gate dielectric layer may also be high K dielectric (which may be formed by Chemical Vapor Deposition process or Atom Layer Deposition process), for example, one of HfO₂, HfSiO, HfSiON, HfTaO, HfSiO, HfZrO, Al₂O₃, La₂O₃, ZrO₂, LaAlO or the combination thereof, with the thickness of 2 nm-10 nm. The dummy gate 6 may be formed by various materials commonly used in the art. Furthermore, it is also possible that the gate dielectric layer 7 is not included in the dummy gate stack.

Then, after forming the dummy gate stack, primary spacers 20 are formed surrounding the dummy gate stack. SiN, SiO₂, SiON or the like can be used as the material for the primary spacers 20. The skilled person in the art, based on the knowledge they have, would have no difficulty in realizing the depositing process and parameters for forming the primary spacers 20.

Preferably, after the step of defining the active area on the semiconductor substrate 1, and forming the dummy gate stack on the active area and the primary spacers 20 surrounding the dummy gate stack, and before the step of forming the insulating layer surrounding the primary spacers 20, the method further comprises: forming a metal silicide 3 in the source/drain regions 2. After the primary spacers 20 surrounding the gate stack is formed on the active area, an alloy of a metal for example Ni (e.g. NiPt) or Ni is deposited on the active area closely surrounding the primary spacers 20, or preferably, for convenience of depositing, on the surface of the whole primary spacers 20 and the active area. Then, with an annealing process, Ni diffuses into the active area and reacts with Si in the semiconductor substrate 1, thus forming Ni silicide. Then, Ni or Ni alloy which has not reacted is removed, so that Ni silicide can enable the low resistance connection between the source/drain contacts formed later and the corresponding source/drain regions. Of course, in an alternative embodiment of the present invention, the source/drain regions 2 may also be formed by doping, implanting or the like, after forming the dummy gate stack and before forming the primary spacers 20. In another embodiment of the present invention, the source/drain regions 2 may also be formed by doping, implanting or the like, after forming the insulating layer surrounding the primary spacers 20.

Then, an insulating layer surrounding the primary spacers 20 is formed on the active area. In the embodiment where metal silicide 3 (e.g. Ni silicide) has already been formed in the active area, an insulating layer surrounding the primary spacers 20 is formed on the Ni silicide. The insulating layer shown in FIG. 2 comprises dual insulating layer, i.e., a first insulating layer 4 being close to the active area and covering the primary spacers 20, and a second insulating layer 5 being relatively far away from the active area and covering the first insulating layer 4. To prevent oxygen or oxygen ion from diffusing into the metal gate and thus reacting with the metal gate, the first insulating layer 4 preferably is an oxygen-free material, for example SiN. Of course, the skilled person in the art can also choose other suitable oxygen-free materials, for example SiC. After the first insulating layer 4 is formed, a second insulating layer 5 is deposited. Preferably, the second insulating layer 5 is also a dual-layer insulating layer structure (not shown in FIG. 2). Namely, the second insulating layer 5 may comprise a SiO₂ layer close to the first insulating layer 4 and a SiN layer deposited on the SiO₂ layer. Preferably, in case that the first insulating layer 4 is formed by SiN material, the SiO₂ layer close to the first insulating layer 4 and the SiN layer on the SiO₂ layer in the second insulating layer 5 help to improve selectivity of the etchant used in the process of forming source/drain contact holes in the first insulating layer 4 and the second insulating layer 5 by etching. The reason lies in that the same etchant always shows different etching rates for SiO₂ and SiN, so that it helps to prevent damage to the primary spacers 20 and even to the gate material during forming the source/drain contact holes by etching. Of course, in another embodiment of the present invention, it is also possible to use only a single insulating layer, i.e., the first insulating layer 4 or the second insulating layer 5. This case is not shown in FIG. 2.

Alternatively, as mentioned above, in the embodiment where source/drain regions 2 are formed by doping, implanting, or the like after forming the insulating layer, the source/drain regions 2 are formed by doping or implanting the desired ions, with the first insulating layer 4 and the second insulating layer 5 being used as a mask. The skilled person in the art, based on the knowledge they have, would have no difficulty in determining the process parameters like types of ion, dose, and time of the doping or implanting, which is not repeated herein for simplicity.

Then, as shown in step S102, the dummy gate 6 in the dummy gate stack is removed to form the first recessed portion 8 surrounded by the primary spacers 20, as shown in FIG. 3. Since the insulating layer is usually higher than that of the dummy gate stack due to deposition of the insulating layer, it is thus required to remove a portion of the insulating layer by means of a planarization process like chemical mechanical polishing, so as to expose the dummy gate 6 in the dummy gate stack. In the description of the present invention, the reason the gate is called a dummy gate and the gate stack is called as a dummy gate stack at this time lies in that, it is required to remove the gate in the gate stack in the subsequent process steps. Therefore, the presence of the gate in the gate stack is only temporary, and in a real sense it is not the gate in the finished transistor. FIG. 3 is a cross-sectional view after removing the dummy gate 6 on the substrate shown in FIG. 2. On the premise that there is no loss in the gate dielectric layer 7, the dummy gate 6 can be removed selectively by means of dry etching or wet etching, so that the upper surface 9 of the gate dielectric layer 7 is exposed and the first recessed portion 8 is formed. Preferably, the dummy gate 6 is completely removed.

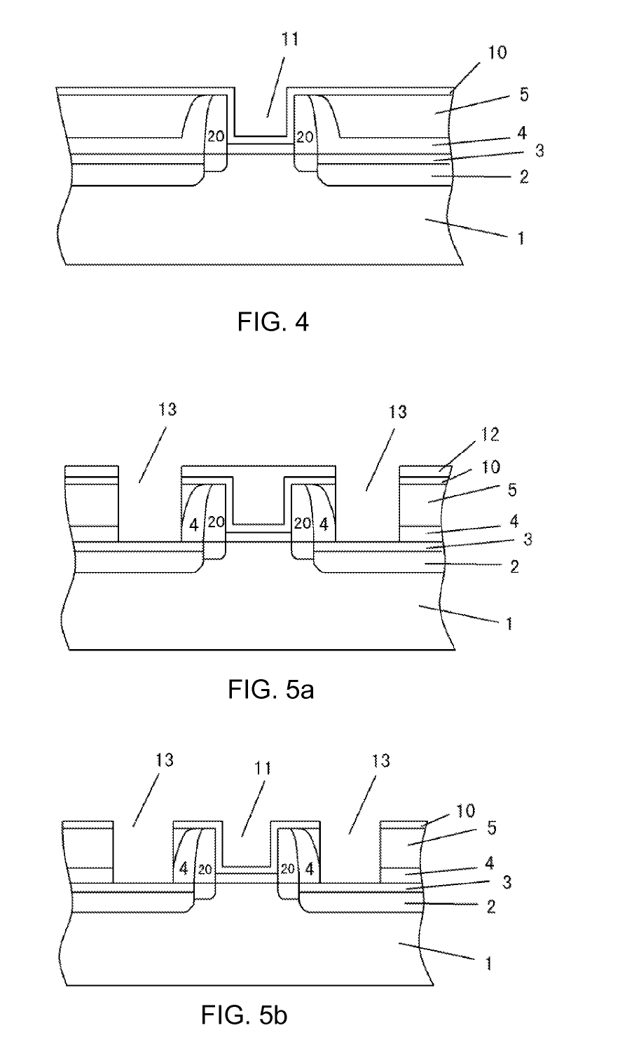

Then, continuing to step S103, Cu is filled simultaneously in the first recessed portion 8 and the source/drain contact holes penetrating the insulating layer to form a gate and source/drain contacts. Optionally, step S103 may further comprise: depositing on the surface of the first recessed portion 8 a gate work function metal layer 10 to form a second recessed portion 11. For convenience in manufacturing, preferably, as shown in FIG. 4 in a cross-sectional view, a layer of metal layer is deposited as a gate work function metal layer 10 simultaneously on the upper surface of the gate dielectric layer, the side face of the first recessed portion, the surface of the primary spacers 20, and the surface of the insulating layer comprising the first insulating layer 4 and the second insulating layer 5. The gate work function metal layer 10 comprises a metal with a specific work function, so that the transistor has a corresponding performance. Different metals can be used in the gate work function metal layer 10 in different devices. Generally, TiN can be used as the metal. Besides, TaN, TaSiN, TiAlN or the like can be used. The deposition of the gate work function metal layer 10 can be performed by atomic layer deposition (ALD), physical chemical vapor deposition (PVD), or chemical vapor deposition (CVD). Preferably, the deposited gate work function metal layer 10 is distributed uniformly on the bottom of the first recessed portion 8, i.e., on the upper surface 9 of the gate dielectric layer 7.

Optionally, step S103 may further comprise: forming two third recessed portions 13 penetrating the insulating layer at positions corresponding to the source/drain regions 2. In this regard, reference can be made to FIGS. 5a-5b. As schematically shown in FIG. 5a, the surface of the gate work function metal layer 10 is covered with a photoresist film 12. The pattern for the source/drain contact holes are transferred onto the photoresist film 12 by lithography. Then by etching the gate work function metal layer 10, the second insulating layer 5, and the first insulating layer 4 at regions corresponding to the source/drain contact holes (also referred to as a third recessed portion 13), the resulting structure is shown in FIG. 5a as a cross-sectional view penetrating the gate work function metal layer 10, the second insulating layer 5, and the first insulating layer 4.

After etching the source/drain contact holes, the metal silicide 3 for contact is exposed. FIG. 5b is a cross-sectional view of the structure after removing the photoresist film 12. Three recesses are shown in FIG. 5b, i.e., the second recessed portion 11 and two source/drain contact holes (the third recessed portion 13). As is known to the skilled person in the art, since the source/drain contact holes are basically symmetric with respect to the gate, the term source/drain contact holes are exchangeable.

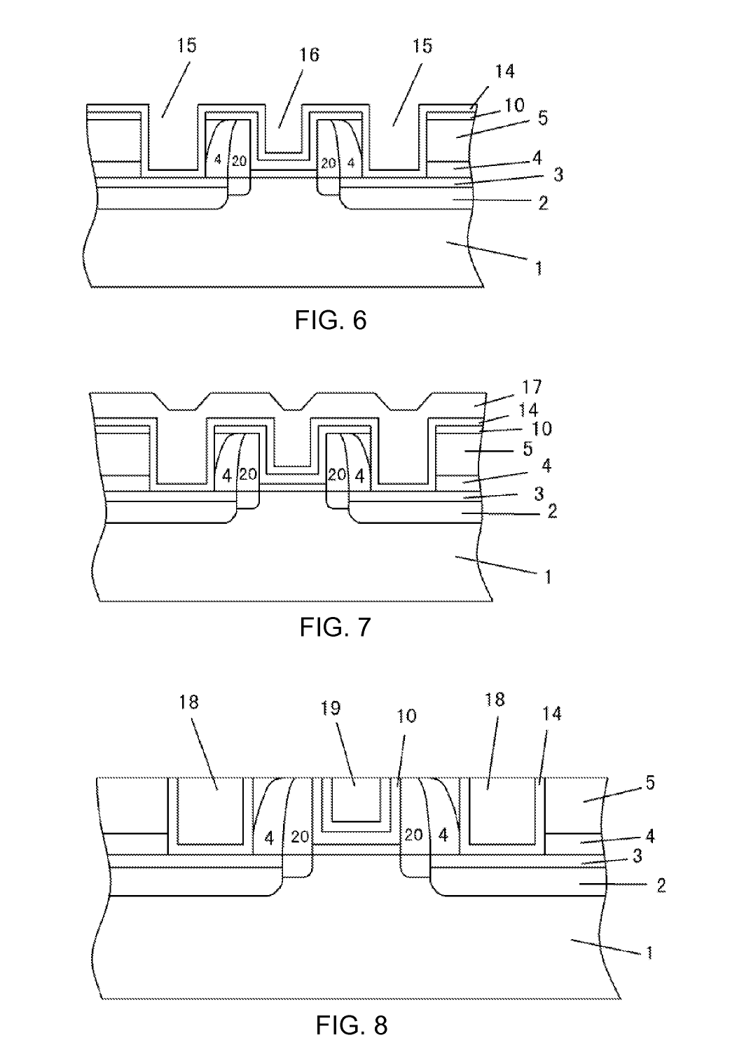

Optionally, step S103 may further comprise: depositing a metal barrier layer 14 on the surface of the second recessed portion 11 and two third recessed portions 13, to form a fourth recessed portion 16 and two fifth recessed portions 15, respectively. Preferably, for convenience in manufacturing, a metal barrier layer 14 is deposited on the whole surface of the substrate shown in FIG. 5b, i.e., simultaneously on the gate work function metal layer 10, the whole inner surface of the source/drain contact holes 13, the primary spacers 20, the surface of the insulating layer comprising the first insulating layer 4 and the second insulating layer 5, and the whole inner surface of the second recessed portion 11. FIG. 6 is a cross-sectional view showing the structure in which a layer of metal barrier layer 14 is deposited on the whole surface of the substrate shown in FIG. 5b. However, depositing the metal barrier layer 14 simultaneously is only an example, and the present invention is not limited to this. The metal barrier layer 14 can prevent the metal Cu filled subsequently from diffusing into the device region, which may degrade the device performance. At the same time, the metal barrier layer 14 can improve the adhesion between the subsequently filled metal and the substrate material (the material covered by the metal barrier layer 14), thus avoiding the subsequently filled metal detaching from the substrate material. In addition, the metal barrier layer 14 serves as the current path and seed layer for crystallization during filling Cu by plating. Preferably, the metal barrier layer 14 is a multi-layer structure, which generally comprises Ta/TaN, and can also comprise Ta/TaN/Ru, TaN/Cu or the like. The metal barrier layer 14 can be deposited by atomic layer deposition (ALD), physical vapor deposition (PVD), chemical vapor deposition (CVD), or the like. As is known to the skilled person in the art, as for different metals, different deposition methods can be used. After the deposition of the metal barrier layer 14, the second recessed portion 11 and the source/drain contact holes (the third recessed portion 13) develop into the fourth recessed portion 16 and the fifth recessed portion 15 which are narrower in space.

What is claimed is:

1. A method for manufacturing a transistor, comprises:
defining an active area on a semiconductor substrate, forming a dummy gate stack on the active area, primary spacers surrounding said dummy gate stack, and an insulating layer surrounding said primary spacers, and forming source/drain regions embedded in said active area;
removing the dummy gate in said dummy gate stack to form a first recessed portion surrounded by the primary spacers;
filling Cu simultaneously in said first recessed portion and in the source/drain contact holes penetrating said insulating layer to form a gate and source/drain contacts.

2. The method according to claim 1, wherein after the step of defining the active area on the semiconductor substrate, forming the dummy gate stack on the active area and the primary spacers surrounding said dummy gate stack, and before the step of forming the insulating layer surrounding said primary spacers, further comprises:
forming metal silicide in said source/drain regions.

3. The method according to claim 1, wherein the step of filling Cu simultaneously in said first recessed portion and in the source/drain contact holes penetrating said insulating layer to form a gate and source/drain contacts comprises:
depositing a gate work function metal layer on the surface of said first recessed portion to form a second recessed portion.

4. The method according to claim 3, further comprises:
forming two third recessed portions penetrating said insulating layer at positions corresponding to said source/drain regions.

5. The method according to claim 4, further comprises:
depositing a metal barrier layer on the surface of said second recessed portion and said two third recessed portions to form a fourth recessed portion and two fifth recessed portions, respectively.

6. The method according to claim 5, further comprises:
depositing Cu on the surface of said fourth recessed portion and two fifth recessed portions, so that Cu fills said fourth recessed portion and two fifth recessed portions simultaneously.

7. The method according to claim 6, further comprises:
planarizing the filled Cu to expose the insulating layer, thus forming a Cu gate and Cu source/drain contacts.

8. The method according to claim 1, wherein said step of forming a dummy gate stack over the active area comprises:
forming a gate dielectric layer on the active area;
forming a dummy gate on said gate dielectric layer.

9. The method according to claim 2, wherein said semiconductor substrate is Si substrate, said metal silicide is Ni silicide.

10. The method according to claim 1, wherein said step of removing said dummy gate comprises completely removing said dummy gate.

11. A method for manufacturing a semiconductor device, comprises the steps of the method for manufacturing a transistor according to any one of claim 1.

12. A transistor, comprises:
an active area over a semiconductor substrate; a gate stack over the active area, primary spacers surrounding said gate stack, and an insulating layer surrounding said primary spacers; and source/drain regions embedded in said active area,
characterized in that,
both the gate in said gate stack and the source/drain contacts penetrating said insulating layer comprise Cu.

13. The transistor according to claim 12, further comprises metal silicide in the surface of the source/drain regions.

14. The transistor according to claim 12, wherein said gate stack further comprises a gate dielectric layer over the active area and a gate over said gate dielectric layer.

15. The transistor according to claim 14, wherein said gate stack further comprises a gate work function metal layer over said gate dielectric layer.

16. The transistor according to claim 15, wherein said gate stack further comprises a metal barrier layer over said gate work function metal layer.

17. The transistor according to claim 16, wherein said gate stack further comprises a Cu gate over said metal barrier layer.

18. The transistor according to claim 13, further comprises a metal barrier layer between said source/drain contacts and said metal silicide.

19. The transistor according to claim 18, wherein said source/drain contacts comprise Cu filled on the surface of said metal barrier layer.

20. The transistor according to claim 13, wherein said semiconductor substrate is Si substrate, and said metal silicide is Ni silicide.

21. A semiconductor device, comprises the transistor according to any one of claim 12.
